(19) United States
(12) Patent Application Publication
(10) Pub. No.: US 2011/0006412 A1
(43) Pub. Date: Jan. 13, 2011

(54) SEMICONDUCTOR CHIP PACKAGE AND METHOD FOR MANUFACTURING THEREOF AND STACK PACKAGE USING THE SAME

(75) Inventor: Hyeong Seok Choi, Seoul (KR)

Correspondence Address: LADAS & PARRY LLP, 224 SOUTH MICHIGAN AVENUE, SUITE 1600, CHICAGO, IL, 60604, US

(73) Assignee: HYNIX SEMICONDUCTOR INC., Gyeonggi-do (KR)

(21) Appl. No.: 12/640,113

(22) Filed: Dec. 17, 2009

(30) Foreign Application Priority Data
Jul. 7, 2009 (KR) 10-2009-0061751

(51) Int. Cl. H01L 25/065; H01L 23/488; H01L 21/60

(52) U.S. Cl. 257/686; 257/692; 438/121; 257/E23.023; 257/E23.141; 257/E25.013; 257/E21.509

(57) ABSTRACT

A semiconductor chip package and method for manufacturing thereof and stack package using the same is presented that reduces electrical signal transmission delays and realizes a reduction in thickness is presented. The stack package includes a plurality of semiconductor chip packages coupled to a substrate. Each semiconductor chip package includes a substrate and a device layer attached to the substrate. The device layer has first bonding pads on a first surface and second bonding pads on a second surface opposite to the first surface. The first and second bonding pads are coupled together by through electrodes that pass through the device layer. The stack package also includes conductive materials attached to the second bonding pads such that the conductive materials couple together adjacent semiconductor chip packages and the substrate.

### CROSS-REFERENCE TO RELATED APPLICATION

The present application claims priority to Korean patent application number 10-2009-0061751 filed on Jul. 7, 2009, which is incorporated herein by reference in its entirety.

### BACKGROUND OF THE INVENTION

The present invention relates to a semiconductor chip package and method for manufacturing thereof. More particularly the present invention relates to a semiconductor chip package and method for manufacturing thereof and stack package using the same in which the semiconductor packages that include the same are configured to reduce electrical signal transmission delays and realize a reduction in thickness.

Packaging technologies for a semiconductor integrated device have been continuously developed to satisfy the omnipresent demands for even more miniaturization and higher capacities. Recently, various technologies for a stack type semiconductor package, which is capable of satisfying some of these demands for mounting efficiency as well as miniaturization and high capacity, have been developed.

At the moment, stack type semiconductor packages that use metal wire are widely used. Stack type semiconductor package can be manufactured by connecting a plurality of semiconductor chips stacked onto a substrate by using a plurality of metal wires, and subsequently molding the upper surface of the substrate including the semiconductor chips.

However, conventional stack type semiconductor package that use metal wires suffer a number of unwanted properties. Since an electrical signal exchange is transmitted through the metal wire, a high number of wires are used which results in lowering transmission speeds and results in deteriorating in electrical properties.

Further, the need for the formation of the metal wires necessitates an additional area on the substrate itself and thereby increases the size of the package and the necessary space required between the semiconductor chips for bonding the metal wires which can increase the height of the package.

Therefore, these and other reasons leads to increased electrical connection lengths between the semiconductor chips and prevents the stack type semiconductor packages from being easily applied to high-speed operation products.

### SUMMARY OF THE INVENTION

An embodiment of the present invention is directed to a semiconductor chip package which reduces delay in transmission of an electrical signal and a method for manufacturing the same.

Also, the embodiment of the present invention is directed to a light, slim, and compact semiconductor chip package and a stack package including the same, which can be adapted to for high-speed operations, and a method for manufacturing thereof.

In the embodiment, a semiconductor chip package comprises a semiconductor substrate; and a device layer having a plurality of first bonding pads which are formed to be exposed outside on a first surface of the device layer attached to the semiconductor substrate and a plurality of second bonding pads which are formed on a second surface opposite to the first surface being electrically connected to the first bonding pads.

The semiconductor substrate is etched so as to expose the first bonding pads.

The semiconductor chip package further comprises a plurality of conductive materials attached onto the second bonding pads.

The conductive materials include bumps.

The semiconductor chip package further comprises a redistribution layer formed on the second surface of the device layer and electrically connected to the second bonding pads; and a plurality of conductive materials attached onto potions of the redistribution layer.

The conductive materials include bumps.

In the embodiment, a method for manufacturing a semiconductor chip package comprises the steps of preparing a semiconductor substrate; forming a plurality of first bonding pads on the semiconductor substrate; forming a device layer having a plurality of second bonding pads which are formed on a second surface opposite to a first surface attached to the semiconductor substrate and electrically connected to the first bonding pads on the semiconductor substrate including the first bonding pads; removing a partial thickness of the semiconductor substrate by implementing a back-grinding process; and exposing the first bonding pads by etching the semiconductor substrate.

After exposing the first bonding pads, the method for manufacturing a semiconductor chip package further comprises the step of attaching a plurality of conductive materials onto the second bonding pads formed on the second surface of the device layer.

The conductive materials are formed of bumps.

After forming the device layer, the method for manufacturing a semiconductor chip package further comprises the steps of forming a redistribution layer electrically connected to the second bonding pads of the second surface of the device layer; and attaching a plurality of conductive materials onto portions of the redistribution layer.

The conductive materials are formed of bumps.

In the embodiment, a stack package comprises a substrate having an upper surface and a bottom surface opposite to the upper surface, and a plurality of bond fingers which are formed on the upper surface; and at least two or more of semiconductor chip modules stacked on the upper surface of the substrate, each of the semiconductor chip packages comprising;

a semiconductor substrate; a device layer having a plurality of first bonding pads which are formed on a first surface of the device layer attached to the semiconductor substrate so as to expose the first bonding pads and a plurality of second bonding pads which are formed on a second surface opposite to the first surface being electrically connected to the first bonding pads; and a plurality of conductive materials attached onto the second bonding pads,

wherein the semiconductor chip package and the substrate are electrically connected to each other by the conductive materials.

The stack package further comprises a redistribution layer having a plurality of conductive materials attached onto the redistribution layer and electrically connected to the second bonding pads of the second surface of the device layer.

The connective materials are formed of bumps.

The stack package further comprises a molding material which is formed to mold the upper surface of the substrate including the stacked semiconductor chip modules; and a plurality of outer connecting terminals attached to the lower surface of the substrate.

### BRIEF DESCRIPTION OF THE DRAWINGS

FIG. 1 is a cross-sectional view illustrating a semiconductor chip package in accordance with one embodiment of the present invention.

FIG. 2 is a cross-sectional view illustrating a semiconductor chip package in accordance with another embodiment of the present invention.

FIGS. 3a to 3e are cross-sectional process views illustrating a method for manufacturing a semiconductor chip package in accordance with an embodiment of the present invention.

FIG. 4 is a cross-sectional view illustrating a stack package in accordance with one embodiment of the present invention.

FIG. 5 is a cross-sectional view illustrating a stack package in accordance with another embodiment of the present invention.

### DESCRIPTION OF SPECIFIC EMBODIMENTS

In a semiconductor chip package according to the present invention, a semiconductor chip package has a semiconductor substrate, and a device layer having a plurality of first bonding pads which are formed to be exposed outside on a first surface of the device layer attached to the semiconductor substrate and a plurality of second bonding pads which are formed on a second surface opposite to the first surface being electrically connected to the first bonding pads.

For stacking the upper and lower semiconductor chip packages, each of the semiconductor chip packages further comprises a plurality of conductive materials which are attached onto the second bonding pads.

In a stack package according to the present invention, the conductive materials attached onto the second bonding pads are respectively inserted into the first bonding pads of an upper semiconductor chip package such that the upper and lower semiconductor chip packages are electrically connected by means of the conductive materials.

Accordingly, in the stack package according to the present invention, the electrical connection paths are shortened between the upper and lower semiconductor chip packages. As a consequence, the stack package of the present invention can reduce the delay in the transmission of an electrical signal.

Therefore, the semiconductor chip package and the stack package including the same according to the present invention can be adapted to for high-speed operations and can be made to be of light, slim, and compact.

Hereafter, a semiconductor chip package in accordance with one embodiment of the present invention will be described in detail.

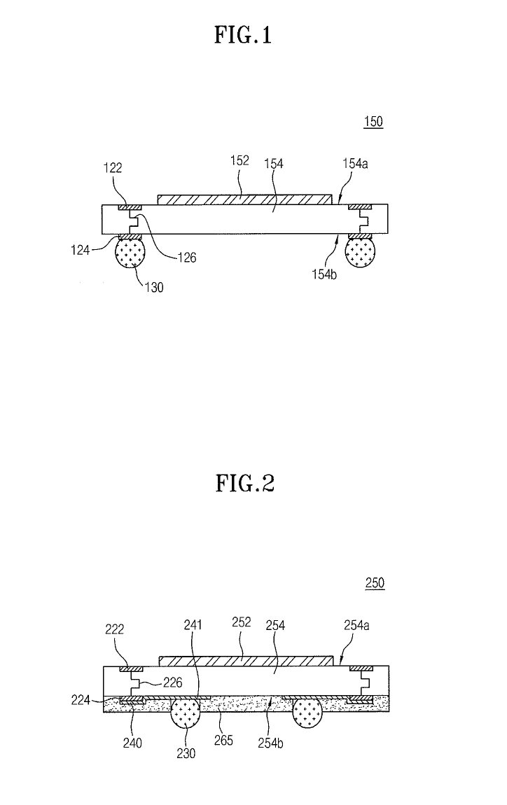

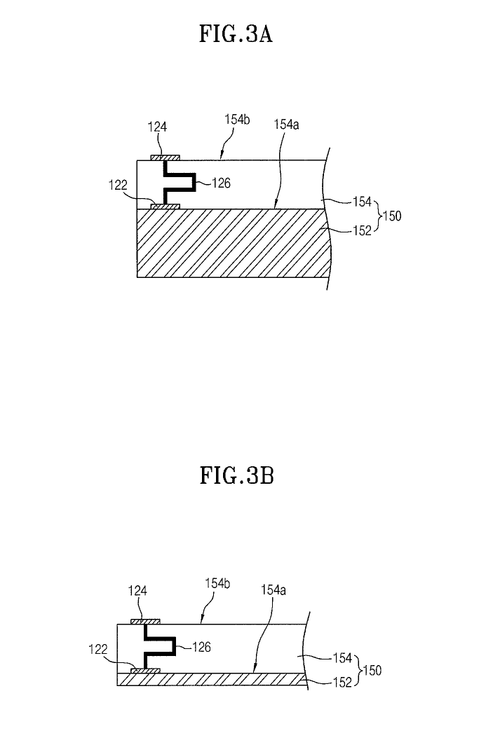

FIG. 1 is a cross-sectional view illustrating a semiconductor chip package in accordance with one embodiment of the present invention. FIG. 2 is a cross-sectional view illustrating a semiconductor chip package in accordance with another embodiment of the present invention.

As shown in FIG. 1, a semiconductor chip package 150 in accordance with one embodiment of the present invention includes a semiconductor substrate 152 and a device layer 154 attached to the semiconductor substrate 152.

The semiconductor substrate 152 may have an upper surface and a lower surface opposite to the upper surface. Also, the device layer 154 may have a first surface 154a attached to any one of the upper and lower surfaces of the semiconductor substrate 152 and a second surface 154b opposite to the first surface 154a.

The device layer 154 has a plurality of first bonding pads 122 and a plurality of second bonding pads 124. The first bonding pads 122 are formed to be exposed outside on the first surface 154a of the device layer 154. The second bonding pads 124 are formed on the second surface 154b and may be being electrically connected to the first bonding pads 122 by through electrodes 126.

Also, the semiconductor chip package 150 may comprise a plurality of conductive materials 130 attached onto the second bonding pads 124.

For example, the conductive materials 130 include bumps. The conductive materials 130 may be formed of at least any one of solder bumps and stud bumps.

The conductive materials 130 may be formed by implementing at least any one of screen printing process and electro-plating process.

The semiconductor substrate 152 is etched so as to expose the first bonding pads 122. Therefore, the first and second bonding pads 122 and 124 are exposed to the outside and are formed on the respective first and second surfaces 154a and 154b of the device layer 154.

The device layer 154 may include a semiconductor circuit part (not shown) and a plurality of through electrodes 126. For instance, the semiconductor circuit part may comprise a data storage part (not shown) so as to storage data and a data process part (not shown) so as to process data.

The through electrodes 126 connect the first bonding pads 122 to the second bonding pads 124 electrically. The through electrodes 126 may be electrically connected to the semiconductor circuit part formed in the device layer 154.

The semiconductor substrate 152 may be used as a bare-state wafer. The semiconductor substrate 152 may be formed of pure silicon. A partial thickness of the lower surface 152a of the semiconductor substrate 152 may be removed by implementing a back-grinding process.

Meanwhile, the bonding position of the second bonding pads 124 can be variously modified by implementing a rerouting process.

As shown in FIG. 2, a semiconductor chip package 250 in accordance with another embodiment of the present invention comprises a semiconductor substrate 252, a device layer 254 and a redistribution layer 240. The redistribution layer 240 is formed on the second surface 254b of the device layer 254 and is electrically connected to the second bonding pads 224.

Also, the semiconductor chip package 250 further comprises a plurality of conductive materials 230 attached onto portions of the redistribution layer 240.

For example, the conductive materials 230 include bumps. The conductive materials 230 may be formed of at least any one of solder bumps and stud bumps.

The redistribution layer 240 may comprise a plurality of redistributed pads 241. The redistributed pads 241 may be formed at the same layer as the redistribution layer 240 and be formed of the same material as the redistribution layer 240. At this time, it is preferable for the conductive materials 230 are attached onto the redistributed pads 241.

The semiconductor chip package 250 can comprise a solder mask 265 which covers the second surface 254b of the device layer 254 including the second bonding pads 224 and the redistribution layer 240 except for the redistributed pads 241.

Hereafter, a method for manufacturing the semiconductor chip package in accordance with an embodiment of the present invention will be described in detail. The manufacturing method of the semiconductor chip package according to an embodiment of the present invention is implemented at a wafer-level.

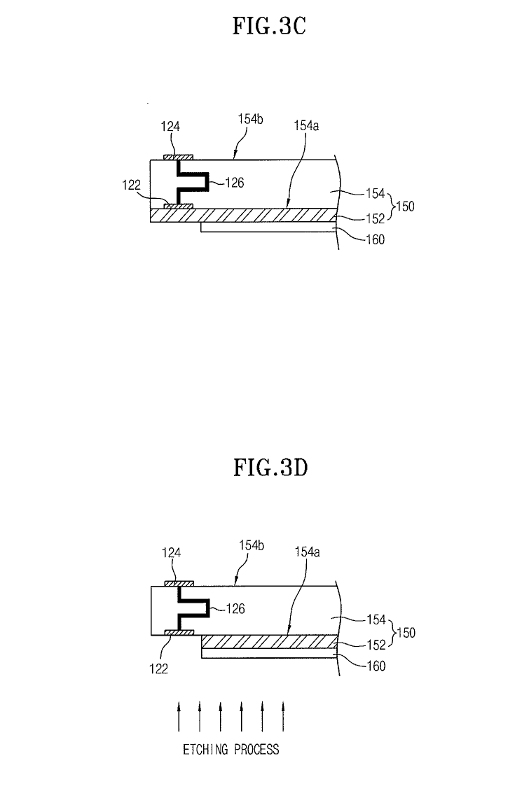

FIGS. 3a to 3e depict cross-sectional process views that illustrate a method for manufacturing a semiconductor chip package in accordance with an embodiment of the present invention.

As shown in FIG. 3a, a semiconductor substrate 152 at a bare-state wafer is prepared. The semiconductor substrate 152 may comprise an upper surface 152a and a lower surface 152b opposite to the upper surface 152a.

Next, a device layer 154 is formed on the semiconductor substrate 152.

The device layer 154 includes a plurality of first bonding pads 122, a plurality of second bonding pads 124, semiconductor circuit part (not shown) and through electrodes 126. The first bonding pads 122 are formed on a first surface 154a of the device layer 154. The second bonding pads 124 are formed on a second surface 154b of the device layer 154 opposite to the first surface 154a and are exposed outside of the device layer 154. Preferably, the second bonding pads 124 may be formed corresponding to the first bonding pads 122 at the first surface 154a of the device layer 154.

The through electrodes 126 couple together the first bonding pads 122 to the second bonding pads 124. As not shown in FIG. 3a, the through electrodes 126 may be electrically connected to the semiconductor circuit part formed in the device layer 154.

For instance, the semiconductor circuit part may comprise a data storage part (not shown) so as to storage data and a data process part (not shown) so as to process data.

Next, as shown in FIG. 3b, a back-grinding process is implemented so as to remove a partial thickness of the lower surface 152b of the semiconductor substrate 152.

As shown in FIG. 3c, a mask layer 160 is formed on the lower surface 152b of the semiconductor substrate 152. A mask layer 160 may be formed of a photo-resist. Next, a mask pattern 160 is formed by implementing lighting process and developing process selectively.

The mask pattern 160 covers entirely on the lower surface 152b of the semiconductor substrate 152 except for the portion of the lower surface 152b of the semiconductor substrate 152 that corresponds to the first bonding pads 122.

As shown in FIG. 3d, the first bonding pads are exposed outside by etching away the portion of the lower surface 152b of the semiconductor substrate 152 which is exposed out from the mask pattern 160.

As shown in FIG. 3e, the mask pattern 160 which remains on the lower surface 152b of the semiconductor substrate 152 is removed by implementing stripping process. Next, a plurality of conductive materials 130 are attached onto the second bonding pads 124. As different from this, the conductive materials 130 can be attached onto the first bonding pads 122.

For example, the conductive materials 130 can include bumps. The conductive materials 130 may be selected from at least one of solder bumps and stud bumps.

The conductive materials 130 may be formed by implementing at least any one of screen printing process and electro-plating process.

Hereafter, a stack package in accordance with one embodiment of the present invention will be described in detail.

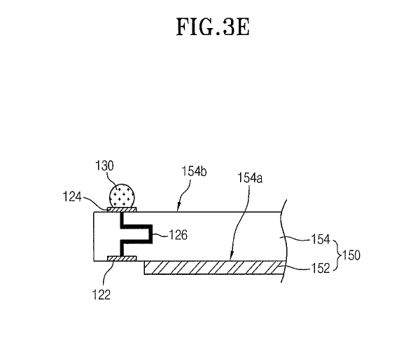

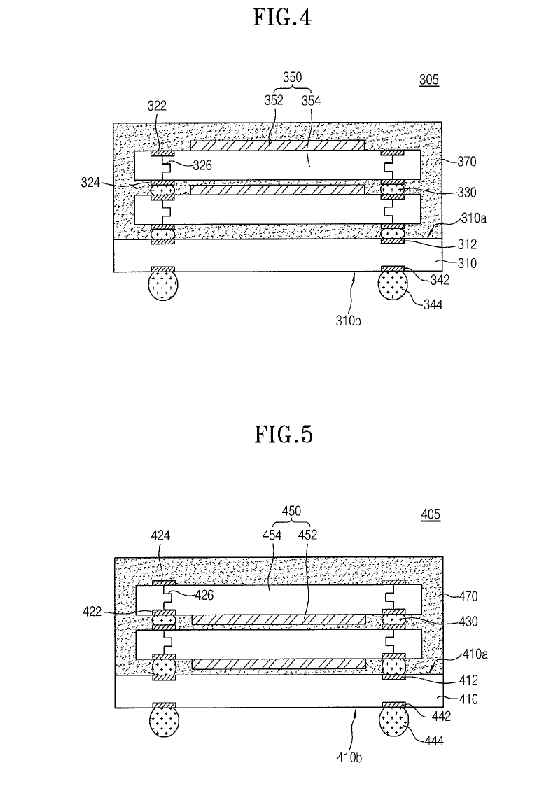

FIG. 4 is a cross-sectional view illustrating a stack package in accordance with one embodiment of the present invention. FIG. 5 is a cross-sectional view illustrating a stack package in accordance with another embodiment of the present invention.

As shown in FIG. 4, a stack package 305 in accordance with one embodiment of the present invention includes a substrate 310 and at least two or more of semiconductor chip packages 350 stacked on the substrate 310.

The substrate 310 has a plurality of bond fingers 312 which are formed on an upper surface 310a of the substrate 310 and a plurality of ball lands 342 which formed on a lower surface 310b of the substrate 310.

Each of the semiconductor chip packages 350 can have a semiconductor substrate 352 and a device layer 354 similar to the structures as any one of the semiconductor chip packages 150 and 250 shown in FIGS. 1 and 2.

At this time, the semiconductor chip packages 350 are stacked on the substrate 310 facing the conductive materials 330 attached to the second bonding pads 322 to the upper surface 310a of the substrate 310.

Therefore, the substrate 310 and the semiconductor chip packages 350 stacked on the substrate 310 can be electrically connected to each other by means of the conductive materials 330.

For example, the conductive materials 330 can include bumps. The conductive materials 330 may be selected from at least one of solder bumps and stud bumps.

The conductive materials 330 may be formed by implementing at least one of screen printing process and electro-plating process.

Also, the stack package 305 can comprise a molding material 370 which covers the upper surface 310a of the substrate 310 including the stacked semiconductor chip packages 350. For instance, the molding material 370 may include epoxy molding compound.

The stack package 305 may further comprise a plurality of outer connecting terminals 344 attached to the lower surface 310b of the substrate 310. The outer connecting terminals 344 can include solder balls.

The aforementioned stack package 305 has the structure in which the first and the second bonding pads 322 and 324 respectively formed on the first and second surfaces 310a and 310b of the device layer 354 are exposed out of the stacked semiconductor chip packages. The first and the second bonding pads 322 and 324 are electrically coupled together by the through electrodes 326

Therefore, the conductive materials 330 can be disposed between an upper semiconductor chip package 350 and a lower semiconductor chip package 350 such that the upper and lower semiconductor chip packages 350 can be electrically connected to each other.

A height of the conductive materials 330 has at least a magnitude more than a thickness of the semiconductor substrate 310. It is preferable for the conductor materials 330 to be formed to have the height to extent that the upper and lower semiconductor chip packages 350 do not cause an electrical fail.

Since the upper and lower semiconductor chip packages 350 are directly contacted to each other by means of the conductive materials 330, the electrically connecting paths are shortened between the upper and lower semiconductor chip packages. As a consequence, the stack package 305 according to one embodiment of the present invention can be adapted for high-speed operations and can be made to be light, slim and compact.

Meanwhile, as shown in FIG. 5, a stack package in accordance with another embodiment of the present invention includes a substrate and at least two or more of semiconductor chip packages stacked on the substrate.

The substrate 410 has a plurality of bond fingers 412 which are formed on an upper surface 410a of the substrate 410 and a plurality of ball lands 442 which formed on a lower surface 410b of the substrate 410.

Each of the semiconductor chip packages 450 can have a semiconductor substrate 452 and a device layer 454 similar to the structures as any one of the semiconductor chip packages 150 and 250 shown in FIGS. 1 and 2.

At this time, the semiconductor chip packages 450 are stacked on the substrate 410 facing the conductive materials 430 attached to the second bonding pads 422 to the upper surface 410a of the substrate 410.

Therefore, the substrate 410 and the semiconductor chip packages 450 stacked on the substrate 410 can be electrically connected to each other by means of the conductive materials 430.

For example, the conductive materials 430 can include bumps. The conductive materials 430 may be selected from at least one of solder bumps and stud bumps.

The conductive materials 430 may be formed by implementing at least one of screen printing process and electro-plating process.

Also, the stack package 405 can comprise a molding material 470 which covers the upper surface 410a of the substrate 410 including the stacked semiconductor chip packages 450. For instance, the molding material 470 may include epoxy molding compound.

The stack package 405 may further comprise a plurality of outer connecting terminals 444 attached to the lower surface 410b of the substrate 410. The outer connecting terminals 444 can include solder balls.

The aforementioned stack package 405 has the structure in which the first and the second bonding pads 422 and 424 respectively formed on the first and second surfaces 410a and 410b of the device layer 454 are exposed out of the stacked semiconductor chip packages. The first and the second bonding pads 422 and 424 are electrically coupled together by the through electrodes 426.

At this time, the stacked semiconductor chip packages are stacked on the substrate opposite to the conductive materials attached to the second bonding pads to the upper surface of the substrate. Also, a stack package in accordance with another embodiment of the present invention further can include conductive materials disposed between the substrate and the lowest semiconductor chip package.

Therefore, stack packages in accordance with embodiments of the present invention can exclude the thickness that the conductive materials occupy in the respective semiconductor chip package. As a consequence, the stack packages according to embodiments of the present invention can be adapted to for high-speed operations and can be made to be light, slim and compact.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A semiconductor chip package comprising:
a semiconductor substrate; and
a device layer attached to an upper surface of the semiconductor substrate, the device layer having a plurality of first bonding pads disposed on a first surface of the device layer and exposed from the semiconductor substrate and a plurality of the second bonding pads disposed on a second surface of the device layer opposite to the first surface.

2. The semiconductor chip package according to claim 1, further comprising through electrodes formed through the device layer that couple the first bonding pads to the second bonding pads.

3. The semiconductor chip package according to claim 1, wherein the semiconductor substrate is etched to expose the first bonding pads.

4. The semiconductor chip package according to claim 1, further comprising a plurality of conductive materials is attached onto the second bonding pads.

5. The semiconductor chip package according to claim 4, wherein the conductive materials include bumps.

6. The semiconductor chip package according to claim 1, further comprising:
a redistribution layer formed on the second surface of the device layer and coupled to the second bonding pads; and
a plurality of conductive materials attached onto portions of the redistribution layer.

7. The semiconductor chip package according to claim 6, wherein the conductive materials include bumps.

8. A method for manufacturing a semiconductor chip package, comprising the steps of:
preparing a semiconductor substrate;
forming a device layer on an upper surface of the semiconductor substrate, the device layer having a plurality of first bonding pads disposed on a first surface of the device layer and a plurality of the second bonding pads disposed on a second surface of the device layer opposite to the first surface;
removing a partial thickness of the semiconductor substrate by implementing a back-grinding process; and
exposing the first bonding pads by etching away a portion of the semiconductor substrate.

9. The method for manufacturing a semiconductor chip package according to claim 8, further comprising attaching a plurality of conductive materials onto the second bonding pads of the device layer after exposing the first bonding pads.

10. The method for manufacturing a semiconductor chip package according to claim 9, wherein the conductive materials are formed of bumps.

11. The method for manufacturing a semiconductor chip package according to claim 8, further comprising the steps of:
forming a redistribution layer on the second surface of the device layer such that the redistribution layer is coupled to the second bonding pads of the device layer, after the step of forming the device layer; and
attaching a plurality of conductive materials onto portions of the redistribution layer.

12. The method for manufacturing a semiconductor chip package according to claim 11, wherein the conductive materials are formed of bumps.

13. A stack package comprising:
a substrate having an upper surface and a lower surface opposite to the upper surface, and having a plurality of bond fingers formed on the upper surface;
a plurality of unit packages stacked on the upper surface of the substrate, each unit package comprising:
a semiconductor substrate;
a device layer attached to an upper surface of the semiconductor substrate, the device layer having a plurality of first bonding pads disposed on a first surface of the device and exposed from the semiconductor substrate and a plurality of the second bonding pads disposed on a second surface of the device layer opposite to the first surface; and
a plurality of conductive materials attached onto the second bonding pads, wherein the conductive materials couples together the unit package and the substrate.

14. The stack package according to claim 13, further comprising a redistribution layer coupled to the conductive materials and coupled to the second bonding pads on the second surface of the device layer.

15. The stack package according to claim 13, wherein the conductive materials are bumps.

16. The stack package according to claim 13, further comprising:
a molding material formed to mold the upper surface of the substrate including the stacked unit packages; and
a plurality of outer connecting terminals attached to the lower surface of the substrate.
